(19) United States
(12) Patent Application Publication
(10) Pub. No.: US 2025/0167055 A1
(43) Pub. Date: May 22, 2025

(54) SEMICONDUCTOR DEVICE INCLUDING TEST STRUCTURE AND METHOD

(71) Applicant: Micron Technology, Inc., Boise, ID (US)

(72) Inventors: Mithun Kumar Ramasahayam, Liberty Hills, TX (US); Amitava Majumdar, Boise, ID (US); Jeffrey D. Runia, Kuna, ID (US); Merri L. Carlson, Boise, ID (US)

(21) Appl. No.: 18/952,448

(22) Filed: Nov. 19, 2024

Related U.S. Application Data
(60) Provisional application No. 63/600,972, filed on Nov. 20, 2023.

(51) Int. Cl. H01L 21/66

(52) U.S. Cl. CPC H01L 22/32

(57) ABSTRACT

Semiconductor devices and associated methods are shown. A device may include an array of memory cells formed on a semiconductor substrate. A device may include one or more test pattern regions located at edges adjacent to the array of memory cells, the one or more test pattern regions including, an array of parallel conductive lines; and wherein selected lines of the array of parallel conductive lines are electrically coupled to ground to detect defects during a test procedure.

### PRIORITY APPLICATION

This application claims the benefit of priority to U.S. Provisional Application Ser. No. 63/600,972, filed Nov. 20, 2023, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates selected portions of a memory device in accordance with some example embodiments.

FIG. 3 illustrates selected portions of a test pattern in accordance with some example embodiments.

FIG. 4 illustrates selected portions of a test pattern in accordance with some example embodiments.

FIG. 5 illustrates selected portions of a test pattern in accordance with some example embodiments.

FIG. 6 illustrates selected portions of a test pattern in accordance with some example embodiments.

FIG. 7 illustrates a semiconductor manufacturing system in accordance with some example embodiments.

FIG. 8A illustrates an image from a test pattern in accordance with some example embodiments.

FIG. 8B illustrates another image from a test pattern in accordance with some example embodiments.

FIG. 9 illustrates an example method flow diagram in accordance with other example embodiments.

FIG. 10 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

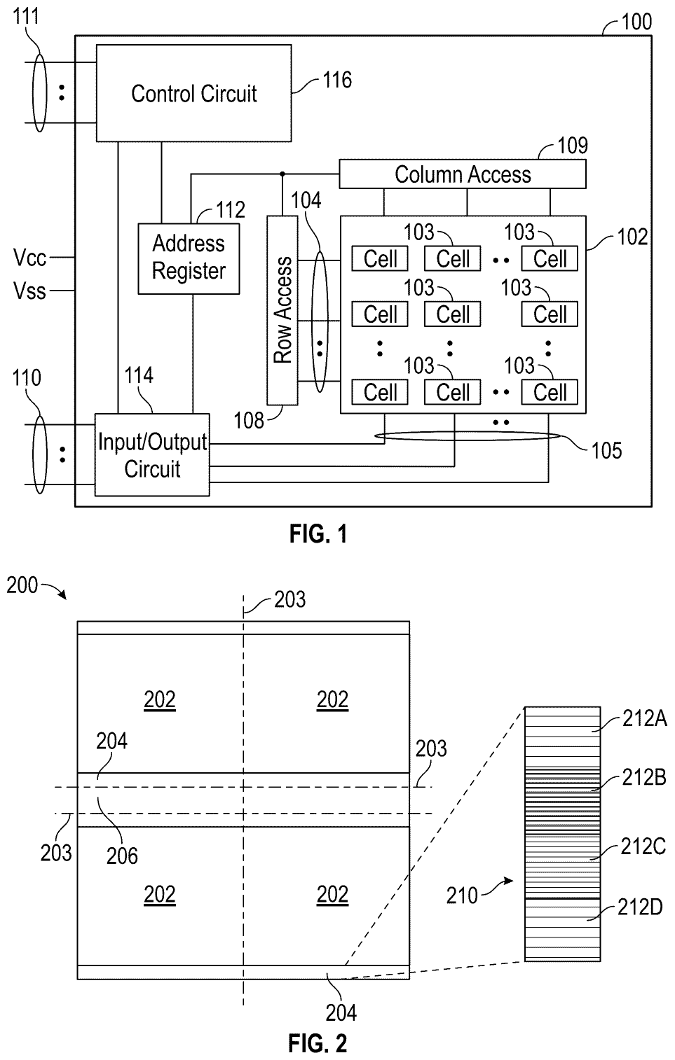

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103. In one example, memory array 102 includes a NAND storage array. In one example, the memory device 100 includes structures as described in FIGS. 2-8.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash that includes NAND memory strings, or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100. One of ordinary skill in the art will recognize that memory device 100 may include other elements, several of which are not shown in FIG. 1, so as not to obscure the example embodiments described herein.

FIG. 2 shows a portion of a semiconductor wafer 200 including a number of semiconductor memory devices 202. Only four semiconductor memory devices 202 are shown for illustration purposes, however a wafer 200 will typically include more than four semiconductor memory devices 202. In one example, the semiconductor memory devices 202 each include an array of memory cells, similar to array 102 shown in FIG. 1. In one example, the semiconductor memory devices 202 each include other components to operate the array of memory cells, similar to the example memory device 100 shown in FIG. 1. In one example, each semiconductor memory devices 202 is subsequently singulated along dashed lines 203 into individual semiconductor dies. Selected examples of wafer 200 may include dummy space 206 between semiconductor memory devices 202, although the invention is not so limited.

A number of test patterns 204 are included in the semiconductor memory devices 202, and are shown located at edges of the semiconductor memory devices 202. The number of test patterns 204 will also be located at edges of each respective array of memory cells in each of the semiconductor memory devices 202. In one example, the number of test patterns 204 are located at edges of the semiconductor memory devices 202 along with peripheral circuitry, such as row access 108 and column access 109 circuitry as shown in FIG. 1.

In the example of FIG. 2, the number of test patterns 204 are each elongated and extend along substantially all of an edge of a semiconductor die. In one example, each semiconductor memory device 202 includes a single test pattern 204. In one example, each semiconductor memory device 202 includes multiple test pattern 204. In the example of FIG. 2, each semiconductor memory device 202 includes elongated test patterns 204 along substantially all of two opposite edges of a semiconductor die. One advantage of elongated test patterns 204 includes the ability to more accurately represent lithographic conditions across the semiconductor memory devices 202. For example, corner of die, and edge of plane effects are represented in the elongated test patterns 204. Elongated test patterns along two opposing edges of a semiconductor die provide more accurate representations of lithographic conditions at four corners of semiconductor memory devices 202. Methodologies and use of the test patterns 204 is discussed in more detail below.

FIG. 2 further shows a magnified view 210 of a portion of a test pattern 204. Multiple test pattern regions 212A-D are shown. The example of FIG. 2 shows four different test pattern regions 212A-D, although the invention is not so limited. Other numbers of test pattern regions, such as one, fewer than 4, or more than four test pattern regions are also within the scope of the present disclosure. In one example, each different test pattern region corresponds to a different lithographic condition in forming a semiconductor feature. Examples of semiconductor features include, but are not limited to, word lines, data lines, and other structures formed by lithography. In one example, structures are formed by pitch quad processing lithography. In one example, each different test pattern region 212A-D corresponds to a different lithographic conditions in pitch quad processing lithography, as described in more detail below.

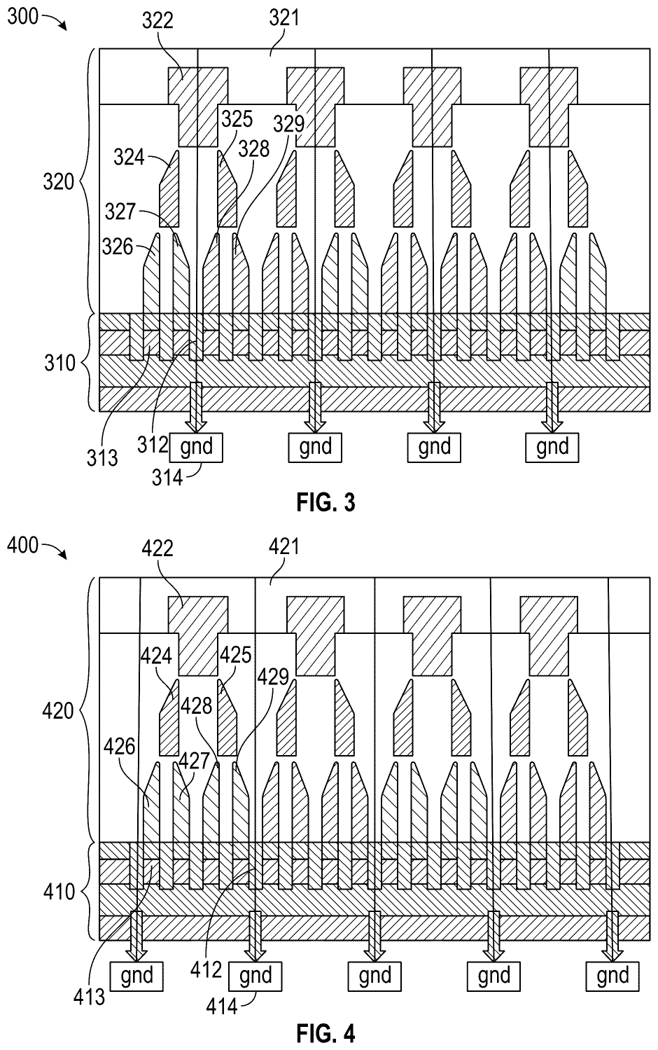

FIG. 3 shows a block diagram representation 300 of a portion 310 of a test pattern similar to test pattern 204. The portion 310 includes a number of parallel conductive lines 312 (shown in cross section looking down a long axis of a line) separated from one another by a dielectric 313. In one example, the number of parallel conductive lines 312 are formed with lithographic conditions similar to wordlines in a memory array such as array 102 from FIG. 1.

In use, the number of parallel conductive lines 312 in the test pattern are characterized and used to indicate similar formation conditions and/or possible similar lithographic defects within similar features in an adjacent memory device. By evaluating an adjacent test pattern, if defects are found in the test pattern, similar defects can be assumed within the adjacent memory device. Process conditions can then be changed to reduce or eliminate defects. In one example, test patterns as described in the present disclosure are evaluated inline with manufacturing. This provides early feedback on possible defect conditions, and allows for adjustment of process conditions before the wafer and memory devices proceed to further manufacturing steps. In one example, by evaluating test patterns as described inline and making process adjustments, weeks in manufacturing adjustments and wasted product can be saved.

Although word lines are used as an example, the invention is not so limited. Evaluation of other lithographically formed structures such as data lines, or other non-linear structures is within the scope of the invention. In one example, lithographically formed structures that are evaluated include additive structures, such as metal deposition structures or other additive metallurgy. In one example, the lithographically formed structures that are evaluated include subtractive structures, such as structures formed by etching or otherwise removing material to form the structures.

In FIG. 3, a lithographic diagram 320 is included to show lithographic conditions used to form the parallel conductive lines 312. The different lithographic conditions may result in different potential defects in the parallel conductive lines 312 of the portion 310 and corresponding lines in the adjacent memory device. Understanding which lithographic condition is leading to a defect provides information on which different process condition changes to make to remove the defect in subsequent manufacture.

A first resist element 322 is shown. The first resist elements 322 define spaces 321 between resist elements 322. In manufacture, each resist element 322 defines a first pair of carbon mask elements 324, 325. Each of the pair of carbon mask elements 324, 325 each further define a second pair of carbon mask elements 326, 327 and a third pair of carbon mask elements 328, 329. The process of using a high level component to define a lower level component is sometimes call a dual damascene process. In the example described in FIG. 3, the process is called pitch quad processing. Pitch quad processing allows formation of very small features such as parallel conductive lines 312 or wordlines that would otherwise be outside the ability of optical lithography using only first resist element 322.

In the example of FIG. 3, the portion 310 corresponds to test pattern region 212A from FIG. 2. In one example, in the portion 310, the parallel conductive lines 312 are electrically coupled to ground 314. In a test procedure, an energetic beam scans the test pattern and if a given parallel conductive line 312 is continuous, with no electrical opens in the line, it will appear consistent in contrast in an image due to electrical interactions between the ground connection 314 and the energetic beam. If there is an electrical open, a portion of the parallel conductive lines 312 that is not coupled to ground, as a result of the electrical open, will appear different from the portion of the parallel conductive line 312 that is coupled to ground. In one example, an energetic beam includes an electron beam. In one example, an electron beam scanning and imaging device is used to inspect the test pattern. Electron beams are advantageous due to their extremely short wavelength, and resulting ability to resolve small features. Although ground voltage is used as an example, coupling selected lines or features in a test pattern to other voltages is also within the scope of the invention. Other voltages will also provide necessary contrast when imaged as described in the present disclosure.

In one example, a parallel conductive line 312 without any electrical opens will appear bright. In another example, a parallel conductive line 312 without any electrical opens will appear dark. One of ordinary skill, having the benefit of the present disclosure, will recognize that imaging settings and electrical bias conditions, etc. may determine whether a parallel conductive line 312 appears bright or dark. In practice, contrast between different portions of a parallel conductive line 312 indicates an open defect.

In the example shown in FIG. 3, portion 310 corresponds to a pitch quad feature formed directly beneath a first resist element 322. As a result, defects that are detected in the portion 310 indicate a lithographic parameter needs adjusting with respect to features formed directly beneath a first resist element 322.

FIG. 4 shows a block diagram representation 400 of a portion 410 of a test pattern similar to test pattern 204. The portion 410 includes a number of parallel conductive lines 412 (shown in cross section looking down a long axis of a line) separated from one another by a dielectric 413. In one example, the number of parallel conductive lines 412 are formed with lithographic conditions similar to wordlines in a memory array such as array 102 from FIG. 1.

In FIG. 4, a lithographic diagram 420 is included to show lithographic conditions used to form the parallel conductive lines 412. A first resist element 422 is shown. The first resist elements 422 define spaces 421 between resist elements 422. In manufacture, each resist element 422 defines a first pair of carbon elements 424, 425. Each of the pair of carbon elements 424, 425 each further define a second pair of carbon elements 426, 427 and a third pair of carbon elements 428, 429.

In the example of FIG. 4, the portion 410 corresponds to test pattern region 212B from FIG. 2. In the portion 410, only selected parallel conductive lines 412 are electrically coupled to ground 414. In the example shown in FIG. 4, portion 410 corresponds to a pitch quad feature formed directly beneath a space element 421. In the example shown in FIG. 4, only features formed directly beneath a space element 421 are coupled to ground 514. As a result, defects that are detected in the portion 410 indicate a lithographic parameter needs adjusting with respect to features formed directly beneath a space element 421. In one example, an electrical open defect is indicated by imaged differences in contrast along a given conductive line 412.

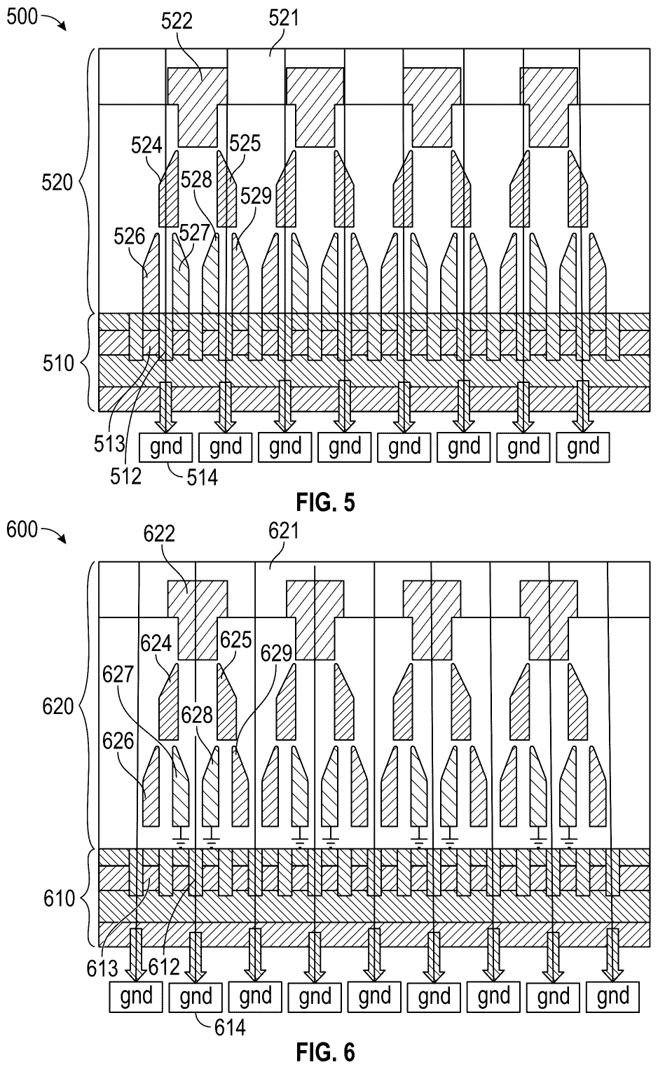

FIG. 5 shows a block diagram representation 500 of a portion 510 of a test pattern similar to test pattern 204. The portion 510 includes a number of parallel conductive lines 512 (shown in cross section looking down a long axis of a line) separated from one another by a dielectric 513. In one example, the number of parallel conductive lines 512 are formed with lithographic conditions similar to wordlines in a memory array such as array 102 from FIG. 1.

In FIG. 5, a lithographic diagram 520 is included to show lithographic conditions used to form the parallel conductive lines 512. A first resist element 522 is shown. The first resist elements 522 define spaces 521 between resist elements 522. In manufacture, each resist element 522 defines a first pair of carbon elements 524, 525. Each of the pair of carbon elements 524, 525 each further define a second pair of carbon elements 526, 527 and a third pair of carbon elements 528, 529.

In the example of FIG. 5, the portion 510 corresponds to test pattern region 212C from FIG. 2. In the portion 510, only selected parallel conductive lines 512 are electrically coupled to ground 514. In the example shown in FIG. 5, portion 510 corresponds to a pitch quad feature formed directly beneath a first carbon element 524, 525. In the example shown in FIG. 5, only features formed directly beneath a first carbon element 524, 525 are coupled to ground 514. As a result, defects that are detected in the portion 510 indicate a lithographic parameter needs adjusting with respect to features formed directly beneath a first carbon element 524, 525. In one example, an electrical open defect is indicated by imaged differences in contrast along a given conductive line 512.

FIG. 6 shows a block diagram representation 600 of a portion 610 of a test pattern similar to test pattern 204. The portion 610 includes a number of parallel conductive lines 612 (shown in cross section looking down a long axis of a line) separated from one another by a dielectric 613. In one example, the number of parallel conductive lines 612 are formed with lithographic conditions similar to wordlines in a memory array such as array 102 from FIG. 1.

In FIG. 6, a lithographic diagram 620 is included to show lithographic conditions used to form the parallel conductive lines 612. A first resist element 622 is shown. The first resist elements 622 define spaces 621 between resist elements 622. In manufacture, each resist element 622 defines a first pair of carbon elements 624, 625. Each of the pair of carbon elements 624, 625 each further define a second pair of carbon elements 626, 627 and a third pair of carbon elements 628, 629.

In the example of FIG. 6, the portion 610 corresponds to test pattern region 212D from FIG. 2. In the portion 610, only selected parallel conductive lines 612 are electrically coupled to ground 614. In the example shown in FIG. 6, portion 610 corresponds to a pitch quad features where only every other parallel conductive line is coupled to ground. As a result, defects that are detected in the portion 610 can indicate a short between adjacent lines. In one example, an electrical short defect is indicated by imaged differences in contrast.

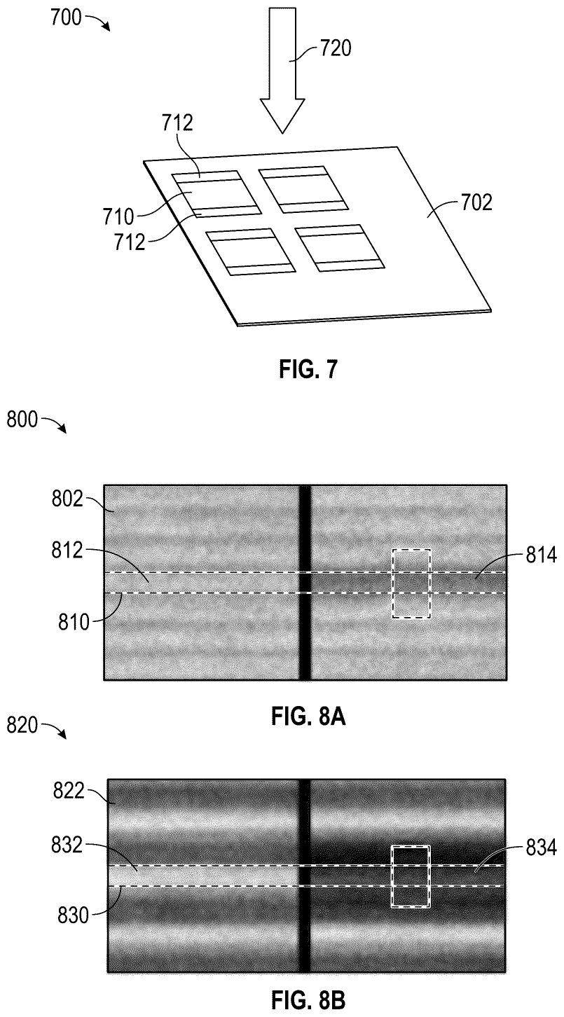

FIG. 7 shows a system 700 for semiconductor manufacture. A wafer 702 is shown including a plurality of dies 710 that include semiconductor memory devices. A number of test patterns 712 similar to test pattern 204 from FIG. 2 are shown. In operation, an energetic beam 720, such as a scanning electron beam, images all or a portion of a surface of the wafer 702. In one example, only test patterns 712 are imaged to save on inspection time. In one example, only selected test patterns 712 are imaged. In one example other portions of the wafer 702 are also imaged.

FIG. 8A shows an example image 800 of a portion of a test pattern as described in the present disclosure. FIG. 8A shows a region as described in FIG. 3, where only lines formed beneath a resist element are coupled to ground. A number of lines 802 are shown. Line 810 shows a first line portion 812 that appears bright in the image 800, and a second line portion 814 that appears dark. The contrast between the first line portion 812 and the second line portion 814 indicates that a defect of an electrical open is present in line 810.

FIG. 8B shows an example image 820 of a portion of a test pattern as described in the present disclosure. FIG. 8B shows a region as described in FIG. 4, where only lines formed beneath a space element are coupled to ground. A number of lines 822 are shown. Line 830 shows a first line portion 832 that appears bright in the image 820, and a second line portion 834 that appears dark. The contrast between the first line portion 832 and the second line portion 834 indicates that a defect of an electrical open is present in line 830.

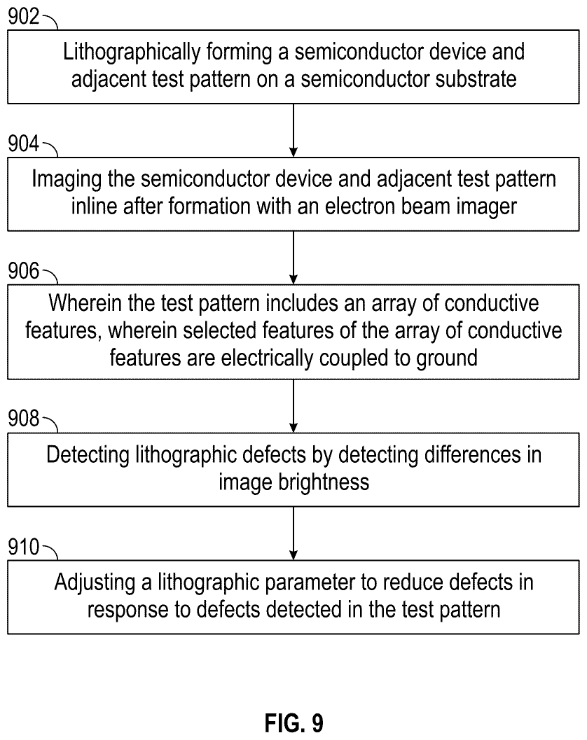

FIG. 9 shows a flow diagram of one example method of manufacture. In operation 902, a semiconductor device and an adjacent test pattern are lithographically formed on a semiconductor substrate. In operation 904, the semiconductor device and the adjacent test pattern are imaged inline after formation with an electron beam imager. In operation 906, the adjacent test pattern includes an array of conductive features, wherein selected features of the array of conductive features are electrically coupled to ground. In operation 908, lithographic defects are detected by detecting differences in image brightness, and in operation 910, a lithographic parameter is adjusted to reduce defects in response to defects detected in the adjacent test pattern.

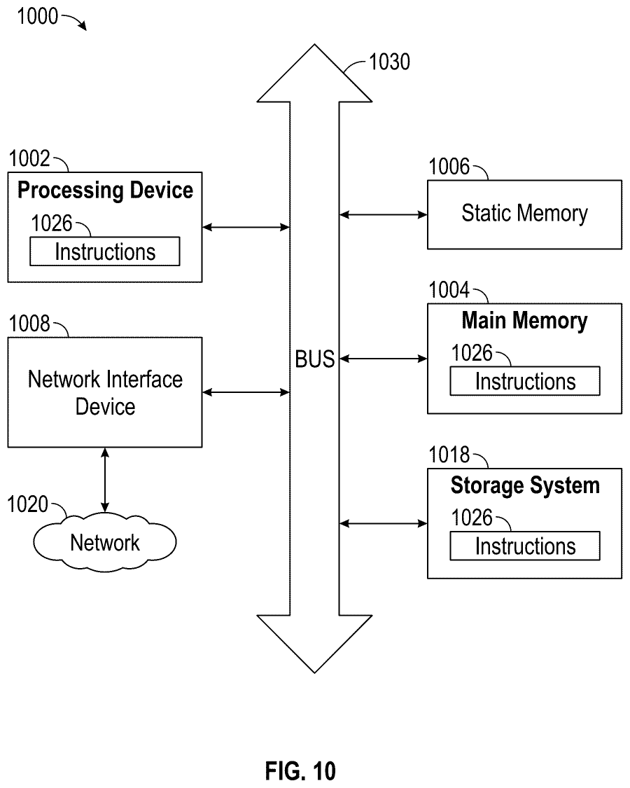

FIG. 10 illustrates a block diagram of an example machine (e.g., a host system) 900 which may include one or more test patterns, memory devices and/or memory systems as described above. As discussed above, machine 1000 may benefit from enhanced memory performance from use of one or more of the described transistor structures and/or memory systems, facilitating improved performance of machine 1000 (as for many such machines or systems, efficient reading and writing of memory can facilitate improved performance of a processor or other components that machine, as described further below.

In alternative embodiments, the machine 1000 may operate as a standalone device or may be connected (e.g., networked) to other machines. In a networked deployment, the machine 1000 may operate in the capacity of a server machine, a client machine, or both in server-client network environments. In an example, the machine 1000 may act as a peer machine in peer-to-peer (P2P) (or other distributed) network environment. The machine 1000 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 1000 may include a processing device 1002 (e.g., a hardware processor, a central processing unit (CPU), a graphics processing unit (GPU), a hardware processor core, or any combination thereof, etc.), a main memory 1004 (e.g., read-only memory (ROM), dynamic random-access memory (DRAM) such as synchronous DRAM (SDRAM) or Rambus DRAM (RDRAM), etc.), a static memory 1006 (e.g., static random-access memory (SRAM), etc.), and a storage system 1018, some or all of which may communicate with each other via a communication interface (e.g., a bus) 1030. In one example, the main memory 1004 includes one or more memory devices as described in examples above.

The processing device 1002 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 1002 can also be one or more special-purpose processing devices such as an application specific integrated circuit (ASIC), a field programmable gate array (FPGA), a digital signal processor (DSP), network processor, or the like. The processing device 1002 can be configured to execute instructions 1026 for performing the operations and steps discussed herein. The computer system 1000 can further include a network interface device 1008 to communicate over a network 1020.

The storage system 1018 can include a machine-readable storage medium (also known as a computer-readable medium) on which is stored one or more sets of instructions 1026 or software embodying any one or more of the methodologies or functions described herein. The instructions 1026 can also reside, completely or at least partially, within the main memory 1004 or within the processing device 1002 during execution thereof by the computer system 1000, the main memory 1004 and the processing device 1002 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 1000 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 1000 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 1026 (e.g., software, programs, an operating system (OS), etc.) or other data are stored on the storage system 1018 can be accessed by the main memory 1004 for use by the processing device 1002. The main memory 1004 (e.g., DRAM) is typically fast, but volatile, and thus a different type of storage than the storage system 1018 (e.g., an SSD), which is suitable for long-term storage, including while in an “off” condition. The instructions 1026 or data in use by a user or the machine 1000 are typically loaded in the main memory 1004 for use by the processing device 1002. When the main memory 1004 is full, virtual space from the storage system 1018 can be allocated to supplement the main memory 1004; however, because the storage system 1018 device is typically slower than the main memory 1004, and write speeds are typically at least twice as slow as read speeds, use of virtual memory can greatly reduce user experience due to storage system latency (in contrast to the main memory 1004, e.g., DRAM). Further, use of the storage system 1018 for virtual memory can greatly reduce the usable lifespan of the storage system 1018.

The instructions 1026 may further be transmitted or received over a network 1020 using a transmission medium via the network interface device 1008 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 1008 may include one or more physical jacks (e.g., Ethernet, coaxial, or phone jacks) or one or more antennas to connect to the network 1020. In an example, the network interface device 1008 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1000, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:
Example 1. A semiconductor device, comprising: an array of memory cells formed on a semiconductor substrate; one or more test pattern regions located at edges adjacent to the array of memory cells, the one or more test pattern regions including; an array of parallel conductive lines; and wherein selected lines of the array of parallel conductive lines are electrically coupled to ground to detect defects during a test procedure.
Example 2. The semiconductor device of example 1, wherein the one or more test pattern regions includes an elongated test pattern along substantially all of an edge of a semiconductor die.
Example 3. The semiconductor device of example 1, wherein one or more test pattern regions includes elongated test patterns along substantially all of two opposite edges of a semiconductor die.
Example 4. The semiconductor device of example 1, wherein the selected lines of the array of parallel conductive lines correspond to different lithographic conditions under which the selected lines were formed.
Example 5. The semiconductor device of example 1, wherein the selected lines of the array of parallel conductive lines correspond to different locations within a pitch quad process.
Example 6. The semiconductor device of example 5, wherein a single test pattern includes four different regions that correspond to four different lithographic conditions under which the selected lines were formed.
Example 7. The semiconductor device of example 6, wherein the four different regions include a first region where only parallel conductive lines that correspond to pitch quad lines formed directly beneath a resist element are coupled to ground.
Example 8. The semiconductor device of example 6, wherein the four different regions include a second region where only parallel conductive lines that correspond to pitch quad lines formed directly beneath a space element are coupled to ground.
Example 9. The semiconductor device of example 6, wherein the four different regions include a third region where only parallel conductive lines that correspond to pitch quad lines formed directly beneath a carbon mask element are coupled to ground.
Example 10. The semiconductor device of example 6, wherein the four different regions include a fourth region where only every other parallel conductive line is coupled to ground.
Example 11. A semiconductor device, comprising: an array of NAND memory strings formed on a semiconductor substrate; one or more test pattern regions located at edges adjacent to the array of NAND memory strings and functionally separated from the array of NAND memory strings, the one or more test pattern regions including; an array of parallel conductive lines formed using pitch quad lithography arranged in multiple test pattern regions; and wherein each test pattern region corresponds to a different lithographic condition in the semiconductor device.
Example 12. The semiconductor device of example 11, wherein the multiple test pattern regions include a first region where only parallel conductive lines that correspond to pitch quad lines formed directly beneath a resist element are coupled to ground.
Example 13. The semiconductor device of example 11, wherein the multiple test pattern regions include a second region where only parallel conductive lines that correspond to pitch quad lines formed directly beneath a space element are coupled to ground.
Example 14. The semiconductor device of example 11, wherein the multiple test pattern regions include a third region where only parallel conductive lines that correspond to pitch quad lines formed directly beneath a carbon mask element are coupled to ground.
Example 15. The semiconductor device of example 11, wherein the multiple test pattern regions include a fourth region where only every other parallel conductive line that corresponds to pitch quad lines are coupled to ground.
Example 16. A method of manufacturing a semiconductor device, comprising: lithographically forming a semiconductor device and an adjacent test pattern on a semiconductor substrate; imaging the semiconductor device and the adjacent test pattern inline after formation with an electron beam imager; wherein the adjacent test pattern includes an array of conductive features, wherein selected features of the array of conductive features are electrically coupled to ground; detecting lithographic defects by detecting differences in image brightness; and adjusting a lithographic parameter to reduce defects in response to defects detected in the adjacent test pattern.
Example 17. The method of example 16, wherein detecting lithographic defects includes detecting defects in additive metallurgy deposited features.
Example 18. The method of example 16, wherein detecting lithographic defects includes detecting differences in image brightness within a first region with only parallel conductive lines that correspond to pitch quad lines formed directly beneath a resist element coupled to ground, and detecting lithographic defects includes detecting open circuit defects in the first region.
Example 19. The method of example 16, wherein detecting lithographic defects includes detecting differences in image brightness within a second region with only parallel conductive lines that correspond to pitch quad lines formed directly beneath a space element coupled to ground, and detecting lithographic defects includes detecting open circuit defects in the second region.
Example 20. The method of example 16, wherein detecting lithographic defects includes detecting differences in image brightness within a third region with only parallel conductive lines that correspond to pitch quad lines formed directly beneath a carbon mask element coupled to ground, and detecting lithographic defects includes detecting open circuit defects in the third region.
Example 21. The method of example 16, wherein detecting lithographic defects includes detecting differences in image brightness within a fourth region with only every other parallel conductive line that corresponds to pitch quad lines are coupled to ground, and detecting lithographic defects includes detecting short circuit defects between adjacent lines.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
an array of memory cells formed on a semiconductor substrate;
one or more test pattern regions located at edges adjacent to the array of memory cells, the one or more test pattern regions including;
an array of parallel conductive lines; and
wherein selected lines of the array of parallel conductive lines are electrically coupled to ground to detect defects during a test procedure.

2. The semiconductor device of claim 1, wherein the one or more test pattern regions includes an elongated test pattern along substantially all of an edge of a semiconductor die.

3. The semiconductor device of claim 1, wherein one or more test pattern regions includes elongated test patterns along substantially all of two opposite edges of a semiconductor die.

4. The semiconductor device of claim 1, wherein the selected lines of the array of parallel conductive lines correspond to different lithographic conditions under which the selected lines were formed.

5. The semiconductor device of claim 1, wherein the selected lines of the array of parallel conductive lines correspond to different locations within a pitch quad process.

6. The semiconductor device of claim 5, wherein a single test pattern includes four different regions that correspond to four different lithographic conditions under which the selected lines were formed.

7. The semiconductor device of claim 6, wherein the four different regions include a first region where only parallel conductive lines that correspond to pitch quad lines formed directly beneath a resist element are coupled to ground.

8. The semiconductor device of claim 6, wherein the four different regions include a second region where only parallel conductive lines that correspond to pitch quad lines formed directly beneath a space element are coupled to ground.

9. The semiconductor device of claim 6, wherein the four different regions include a third region where only parallel conductive lines that correspond to pitch quad lines formed directly beneath a carbon mask element are coupled to ground.

10. The semiconductor device of claim 6, wherein the four different regions include a fourth region where only every other parallel conductive line is coupled to ground.

11. A semiconductor device, comprising:
an array of NAND memory strings formed on a semiconductor substrate;
one or more test pattern regions located at edges adjacent to the array of NAND memory strings and functionally separated from the array of NAND memory strings, the one or more test pattern regions including;
an array of parallel conductive lines formed using pitch quad lithography arranged in multiple test pattern regions; and
wherein each test pattern region corresponds to a different lithographic condition in the semiconductor device.

12. The semiconductor device of claim 11, wherein the multiple test pattern regions include a first region where only parallel conductive lines that correspond to pitch quad lines formed directly beneath a resist element are coupled to ground.

13. The semiconductor device of claim 11, wherein the multiple test pattern regions include a second region where only parallel conductive lines that correspond to pitch quad lines formed directly beneath a space element are coupled to ground.

14. The semiconductor device of claim 11, wherein the multiple test pattern regions include a third region where only parallel conductive lines that correspond to pitch quad lines formed directly beneath a carbon mask element are coupled to ground.

15. The semiconductor device of claim 11, wherein the multiple test pattern regions include a fourth region where only every other parallel conductive line that corresponds to pitch quad lines are coupled to ground.

16. A method of manufacturing a semiconductor device, comprising:
lithographically forming a semiconductor device and an adjacent test pattern on a semiconductor substrate;
imaging the semiconductor device and the adjacent test pattern inline after formation with an electron beam imager;
wherein the adjacent test pattern includes an array of conductive features, wherein selected features of the array of conductive features are electrically coupled to ground;
detecting lithographic defects by detecting differences in image brightness; and
adjusting a lithographic parameter to reduce defects in response to defects detected in the adjacent test pattern.

17. The method of claim 16, wherein detecting lithographic defects includes detecting defects in additive metallurgy deposited features.

18. The method of claim 16, wherein detecting lithographic defects includes detecting differences in image brightness within a first region with only parallel conductive lines that correspond to pitch quad lines formed directly beneath a resist element coupled to ground, and detecting lithographic defects includes detecting open circuit defects in the first region.

19. The method of claim 16, wherein detecting lithographic defects includes detecting differences in image brightness within a second region with only parallel conductive lines that correspond to pitch quad lines formed directly beneath a space element coupled to ground, and detecting lithographic defects includes detecting open circuit defects in the second region.

20. The method of claim 16, wherein detecting lithographic defects includes detecting differences in image brightness within a third region with only parallel conductive lines that correspond to pitch quad lines formed directly beneath a carbon mask element coupled to ground, and detecting lithographic defects includes detecting open circuit defects in the third region.

21. The method of claim 16, wherein detecting lithographic defects includes detecting differences in image brightness within a fourth region with only every other parallel conductive line that corresponds to pitch quad lines are coupled to ground, and detecting lithographic defects includes detecting short circuit defects between adjacent lines.
